(19) United States
(12) Patent Application Publication
(10) Pub. No.: US 2024/0074285 A1
(43) Pub. Date: Feb. 29, 2024

(54) DISPLAY DEVICE AND METHOD FOR REPAIRING THE SAME

(71) Applicant: LG DISPLAY CO., LTD., Seoul (KR)

(72) Inventors: Jaeyoung OH, Goyang-si (KR); Yongmin KIM, Anyang-si (KR)

(73) Assignee: LG DISPLAY CO., LTD., SEOUL (KR)

(21) Appl. No.: 18/239,151

(22) Filed: Aug. 29, 2023

(30) Foreign Application Priority Data
Aug. 29, 2022 (KR) 10-2022-0108587

(51) Int. Cl. H10K 59/80; H10K 59/12; H10K 59/121; H10K 71/00

(52) U.S. Cl. CPC H10K 59/80515; H10K 59/1201; H10K 59/1216; H10K 71/621; H10K 71/861

(57) ABSTRACT

A display device includes a substrate; a plurality of sub-pixels disposed on the substrate and arranged in a first direction and a second direction crossing the first direction; a plurality of anode electrodes included in each of the sub-pixels; and a storage capacitor disposed under and overlapping with each of the anode electrodes, wherein the plurality of anode electrodes include a first anode electrode of the first sub-pixel of the plurality of sub-pixels, and a second anode electrode of the second sub-pixel of the plurality of sub-pixels disposed adjacent to the first sub-pixel along the second direction, and wherein the second anode electrode includes a repair pattern extending along the second direction toward the first sub-pixel to overlap with the storage capacitor of the first sub-pixel.

### CROSS-REFERENCE TO RELATED APPLICATION

This application claims the priority of Korean Patent Application No. 10-2022-0108587 filed on Aug. 29, 2022, which is hereby incorporated by reference in its entirety.

### BACKGROUND

### Field of the Disclosure

The present disclosure relates to a display device and a method for repairing the display device, and more particularly, to a display device including a repair pattern capable of repairing a defective pixel while improving an aperture ratio, and to a method for repairing the display device.

### Description of the Background

A display device is applied to various electronic devices such as TVs, mobile phones, laptops and tablets. To this end, research to develop thinning, lightening, and low power consumption of the display device is continuing.

Examples of the display device include a liquid crystal display device (LCD), a plasma display device (PDP), a field emission display device (FED), an electro-wetting display device (EWD), and an organic light-emitting display device (OLED).

The organic light-emitting display device (OLED) includes a plurality of pixel areas disposed in a display area where an image is displayed, and a plurality of organic light-emitting elements corresponding to the plurality of pixel areas. Since the organic light-emitting element is a self-light-emitting element that emits light by itself, the organic light-emitting display device has the advantages of faster response speed, greater luminous efficiency, luminance and larger viewing angle, and excellent contrast ratio and color reproduction compared to the liquid crystal display device.

In a process of manufacturing the organic light-emitting display device, defects such as bright spots or dark spots may occur in the sub-pixel due to various causes such as foreign matter. The defects occurring in the sub-pixels degrade the quality of the entire display area, thereby reducing the reliability of the display device Accordingly, research is being conducted to repair a defective sub-pixel into a normal sub-pixel.

To implement a high-definition screen, in particular, an ultra-high definition (UHD) screen of 8K in a display device, it is important to secure an aperture ratio. Accordingly, a repair method capable of securing the aperture ratio and converting a defective sub-pixel into a normal sub-pixel is required.

### SUMMARY

Accordingly, the present disclosure is to provide a display device capable of efficiently utilizing a space of a sub-pixel area and securing an aperture ratio to improve a lifespan of an organic light-emitting element.

The present disclosure is also to provide a display device capable of easily succeed in repairing a defective sub-pixel, and increasing an area size of a capacitor area.

In addition, the present disclosure is to provide a display device capable of reducing a resistance of a sensing transistor to stabilize element mobility characteristics.

Further, the present disclosure is to provide a method for repairing a defective sub-pixel in a display device.

The present disclosure is not limited to the above-mentioned purpose. Other advantages according to the present disclosure that are not mentioned may be understood based on following descriptions, and may be more clearly understood based on aspects according to the present disclosure. Further, it will be easily understood that the purposes and advantages according to the present disclosure may be realized using means shown in the claims or combinations thereof.

A display device according to one aspect of the present disclosure includes a substrate; a plurality of sub-pixels disposed on the substrate and arranged in a first direction and a second direction crossing the first direction; a plurality of anode electrode included in each of the sub-pixels; and a storage capacitor disposed under and overlapping with each of the anode electrodes, wherein the plurality of anode electrodes includes a first anode electrode of the first sub-pixel of the plurality of sub-pixels, and a second anode electrode of the second sub-pixel of the plurality of sub-pixels disposed adjacent to the first sub-pixel along the second direction, and wherein the second anode electrode includes a repair pattern extending along the second direction toward the first sub-pixel to overlap with the storage capacitor of the first sub-pixel.

A display device according to another aspect of the present disclosure includes a substrate having a sensing area where a sensing transistor is disposed, and a capacitor area including a repair area; a buffer layer disposed on the substrate and in the sensing area and the repair area; a light-blocking layer disposed between the substrate and the buffer layer and in a portion of the capacitor area except for the repair area; a sensing transistor positioned on the buffer layer and in the sensing area; a storage capacitor disposed on the buffer layer and in the capacitor area including the repair area; a protective layer covering the sensing transistor and the storage capacitor; an overcoat film disposed on the protective layer; a repair hole disposed in the repair area and extending through the overcoat film to expose a portion of a surface of the protective layer; and a repair pattern disposed on an exposed surface of the repair hole and overlapping with the storage capacitor while the protective layer is interposed between the repair pattern and the storage capacitor.

A method for repairing a display device according to still another aspect of the present disclosure is provided. The display device includes: a substrate including a plurality of sub-pixels; a first anode electrode and a storage capacitor included in a first sub-pixel in the plurality of sub-pixels; and a repair pattern extending from a second anode electrode included in a second sub-pixel disposed adjacent to the first sub-pixel, wherein the repair pattern overlap with the storage capacitor of the first sub-pixel, wherein the method comprises irradiating laser onto the repair pattern extending from the second anode electrode to electrically connect the repair pattern of the second sub-pixel to the storage capacitor of the first sub-pixel.

According to the aspects of the present disclosure, the repair area may be disposed in the capacitor area, such that a separate space for the repair pattern may not be disposed therein. Thus, a space margin may be secured and thus, the aperture ratio may be improved.

Accordingly, the repair process may be reliably performed while securing the aperture ratio even in an 8K class ultra-high definition model.

Moreover, the capacitor electrode instead of the light blocking film may be disposed under the repair pattern. Thus, even when the laser irradiation position is misaligned with a target position, the repair process may be prevented or reduced from failing.

Moreover, a single layer structure may be disposed between the repair pattern and the second electrode. Thus, the repair process may be reliably performed at relatively lower laser output energy level compared to that when a multi-layer structure is disposed therebetween. This may prevent or reduce damage to surrounding elements by the laser.

In addition, increasing the area size of the area in which the active layer overlap with the repair area may allow the resistance of the sensing transistor to be reduced, such that mobility characteristics of the element may be stabilized.

Effects of the present disclosure are not limited to the effects mentioned above, and other effects not mentioned will be clearly understood by those skilled in the art from the descriptions below.

### BRIEF DESCRIPTION OF THE DRAWINGS

The accompanying drawings, which are included to provide a further understanding of the disclosure and are incorporated in and constitute a part of the disclosure, illustrate aspects of the disclosure and together with the description serve to explain the principle of the disclosure.

In the drawings:

FIG. 1 is a diagram showing a display device according to an aspect of the present disclosure;

FIG. 2 is a plan view showing a portion of a sub-pixel disposed on a display area of FIG. 1.

FIG. 3 is an enlarged plan view of a partial area of a circuit area in FIG. 2.

FIG. 4 is a cross-sectional view as cut along I-I′ and II-IP of FIG. 3.

FIG. 5A to FIG. 5E are diagrams for illustrating a method for manufacturing a display device according to an aspect of the present disclosure.

FIG. 6A to FIG. 6C are diagrams for illustrating a repair process according to Comparative Example.

FIGS. 7A and 7B are images showing repair results based on laser output energy levels.

FIG. 8 is a plan view showing a display device according to another aspect of the present disclosure.

FIG. 9 is a cross-sectional view as cut along IV-IV′ of FIG. 8.

FIG. 10 is a plan view showing a display device according to still another aspect of the present disclosure.

### DETAILED DESCRIPTION

Advantages and features of the present disclosure, and a method of achieving the advantages and features will become apparent with reference to aspects described later in detail together with the accompanying drawings. However, the present disclosure is not limited to the aspects as disclosed under, but may be implemented in various different forms. Thus, these aspects are set forth only to make the present disclosure complete, and to completely inform the scope of the present disclosure to those of ordinary skill in the technical field to which the present disclosure belongs.

For simplicity and clarity of illustration, elements in the drawings are not necessarily drawn to scale. The same reference numbers in different drawings represent the same or similar elements, and as such perform similar functionality. Further, descriptions and details of well-known steps and elements are omitted for simplicity of the description. Furthermore, in the following detailed description of the present disclosure, numerous specific details are set forth to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure. Examples of various aspects are illustrated and described further below. It will be understood that the description herein is not intended to limit the claims to the specific aspects described. On the contrary, it is intended to cover alternatives, modifications, and equivalents as may be included within the spirit and scope of the present disclosure as defined by the appended claims.

A shape, a size, a ratio, an angle, a number, etc. disclosed in the drawings for describing aspects of the present disclosure are illustrative, and the present disclosure is not limited thereto. The same reference numerals refer to the same elements herein.

The terminology used herein is directed to the purpose of describing particular aspects only and is not intended to be limiting of the present disclosure. As used herein, the singular constitutes “a” and “an” are intended to include the plural constitutes as well, unless the context clearly indicates otherwise. It will be further understood that the terms “comprise”, “including”, “include”, and “including” when used in this specification, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of associated listed items. Expression such as “at least one of” when preceding a list of elements may denote the entire list of elements, and may denote the individual elements of the list, or may denote any combination of the elements of the list. In interpretation of numerical values, an error or tolerance therein may occur even when there is no explicit description thereof.

In addition, it will also be understood that when a first element or layer is referred to as being present “on” a second element or layer, the first element may be disposed directly on the second element or may be disposed indirectly on the second element with a third element or layer being disposed between the first and second elements or layers. It will be understood that when an element or layer is referred to as being “connected to”, or “coupled to” another element or layer, it may be directly on, connected to, or coupled to the other element or layer, or one or more intervening elements or layers may be present. In addition, it will also be understood that when an element or layer is referred to as being “between” two elements or layers, it may be the only element or layer between the two elements or layers, or one or more intervening elements or layers may also be present.

Further, as used herein, when a layer, film, region, plate, or the like is disposed “on” or “on a top” of another layer, film, region, plate, or the like, the former may directly contact the latter or still another layer, film, region, plate, or the like may be disposed between the former and the latter. As used herein, when a layer, film, region, plate, or the like is directly disposed “on” or “on a top” of another layer, film, region, plate, or the like, the former directly contacts the latter and still another layer, film, region, plate, or the like is not disposed between the former and the latter. Further, as used herein, when a layer, film, region, plate, or the like is disposed “below” or “under” another layer, film, region, plate, or the like, the former may directly contact the latter or still another layer, film, region, plate, or the like may be disposed between the former and the latter. As used herein, when a layer, film, region, plate, or the like is directly disposed “below” or “under” another layer, film, region, plate, or the like, the former directly contacts the latter and still another layer, film, region, plate, or the like is not disposed between the former and the latter.

In descriptions of temporal relationships, for example, temporal precedent relationships between two events such as “after”, “subsequent to”, “before”, etc., another event may occur therebetween unless “directly after”, “directly subsequent” or “directly before” is indicated.

When a certain aspect may be implemented differently, a function or an operation specified in a specific block may occur in a different order from an order specified in a flowchart. For example, two blocks in succession may be actually performed substantially concurrently, or the two blocks may be performed in a reverse order depending on a function or operation involved.

It will be understood that, although the terms “first”, “second”, “third”, and so on may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described under could be termed a second element, component, region, layer or section, without departing from the spirit and scope of the present disclosure.

The features of the various aspects of the present disclosure may be partially or entirely combined with each other, and may be technically associated with each other or operate with each other. The aspects may be implemented independently of each other and may be implemented together in an association relationship.

In interpreting a numerical value, the value is interpreted as including an error range unless there is separate explicit description thereof.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, “aspects,” “examples,” “aspects, and the like should not be construed such that any aspect or design as described is superior to or advantageous over other aspects or designs.

Further, the term ‘or’ means ‘inclusive or’ rather than ‘exclusive or’. That is, unless otherwise stated or clear from the context, the expression that ‘x uses a or b’ means any one of natural inclusive permutations.

The terms used in the description below have been selected as being general and universal in the related technical field. However, there may be other terms than the terms depending on the development and/or change of technology, convention, preference of technicians, etc. Therefore, the terms used in the description below should not be understood as limiting technical ideas, but should be understood as examples of the terms for describing aspects.

Further, in a specific case, a term may be arbitrarily selected by the applicant, and in this case, the detailed meaning thereof will be described in a corresponding description section. Therefore, the terms used in the description below should be understood based on not simply the name of the terms, but the meaning of the terms and the contents throughout the Detailed Descriptions.

Hereinafter, a display device according to each aspect of the present disclosure will be described with reference to the accompanying drawings.

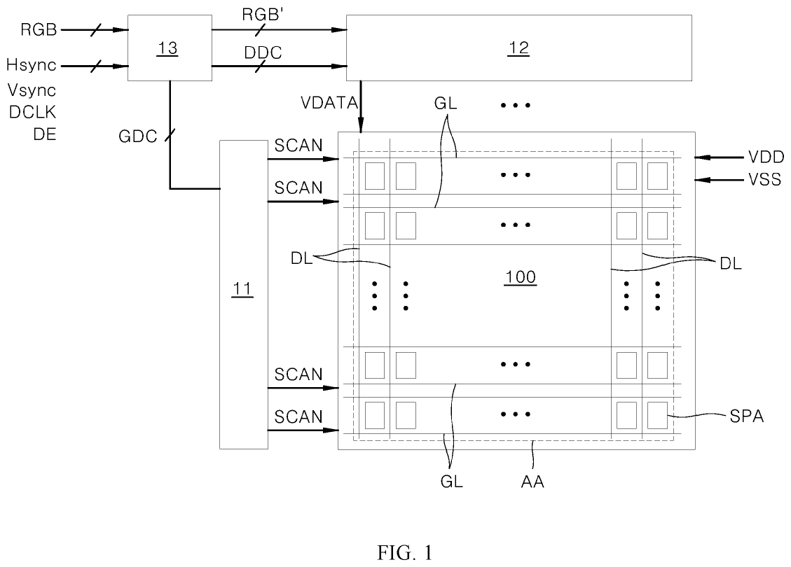

FIG. 1 is a diagram showing a display device according to an aspect of the present disclosure.

Referring to FIG. 1, the display device includes a display panel 100 including a display area AA and a panel driver 11, 12, and 13 for supplying a driving signal to the display panel 100. The display panel 100 includes the display area AA from which an image is output, and a plurality of sub-pixels SPA disposed on the display area AA and arranged in parallel to each other and outputting respective light beams for displaying an image.

Each of the plurality of sub-pixels SPA emits light in a wavelength range corresponding to one color among a plurality of different colors. In this regard, the plurality of colors may include red, green, and blue. However, the present disclosure is not limited thereto. For example, it may include red, green, blue and white.

The display panel 100 further includes signal lines GL and DL connected to the plurality of sub-pixels SPA. The signal lines GL and DL deliver the driving signal of the panel driver 11, 12, and 13 to each sub-pixel SPA. For example, the display panel 100 may include the gate line GL that supplies a scan signal SCAN and a data line DL that supplies a data signal VDATA.

The display panel 100 may further include first and second driving power lines that respectively deliver first and second driving powers VDD and VSS for driving the light-emitting element disposed in each sub-pixel SPA.

The panel driver 11, 12, and 13 of the display device may include the gate driver 11 connected to the gate line GL of the display panel 100, the data driver 12 connected to the data line DL of the display panel 100, and a timing controller 13 that control an operation timing of each of the gate driver 11 and the data driver 12.

The timing controller 13 rearranges digital video data RGB input from an external source according to a resolution of the display panel 100, and supplies the rearranged digital video data RGB′ to the data driver 12.

The timing controller 13 generates and provides a data control signal DDC for controlling the operation timing of the data driver 12, and a gate control signal GDC for controlling the operation timing of the gate driver 11, based on timing signals such as a vertical synchronization signal Vsync, a horizontal synchronization signal Hsync, a dot clock signal DCLK, and a data enable signal DE.

The gate driver 11 sequentially supplies a scan signal SCAN to a plurality of gate lines GL during one frame period for image display based on the gate control signal GDC. In this regard, the gate line GL may correspond to sub-pixels SPA arranged in a line in a horizontal direction among the plurality of sub-pixels SPA.

The data driver 12 converts the rearranged digital video data RGB′ into an analog data voltage based on the data control signal DDC. The data driver 12 supplies data signal VDATA corresponding to each sub-pixel SPA corresponding to each gate line GL to the data line DL during each horizontal period based on the rearranged digital video data RGB′.

Each of the plurality of gate lines GL may extend in a first direction of the display panel 100. Each of the plurality of data lines DL may extend in a second direction intersecting the first direction of the display panel 100. That is, the gate line GL and the data line DL may be disposed to intersect each other.

A plurality of sub-pixels SPA disposed on the display area AA may be arranged in a matrix form (M*N) (where M and N are natural numbers) along the first and second directions. Each sub-pixel SPA may be electrically connected to one gate line of the plurality of gate lines GL and one data line of the plurality of data lines DL.

The plurality of sub-pixel SPA may be arranged to be spaced from each other in the first direction (the X-axis direction) and the second direction (the Y-axis direction). In this regard, the X-axis direction may be referred to as a transverse direction, and the Y-axis direction may be referred to as a longitudinal direction, or vice versa. Each of the plurality of sub-pixels SPA emits light in a wavelength range corresponding to one color among the plurality of different colors. The plurality of different colors may include red as a first color, green as a second color, blue as a third color, and white as a fourth color. Sub-pixels adjacent to each other among the plurality of sub-pixel SPA can constitute a unit pixel which displays various colors via a mixture of the first, second, third and fourth colors. In one aspect of the present disclosure, the unit pixel may include red as red as a first color, green as a second color, and blue as a third color. In the plurality of sub-pixels SPA constituting one unit pixel, sub-pixels disposed along each X-axis direction may emit light of different colors.

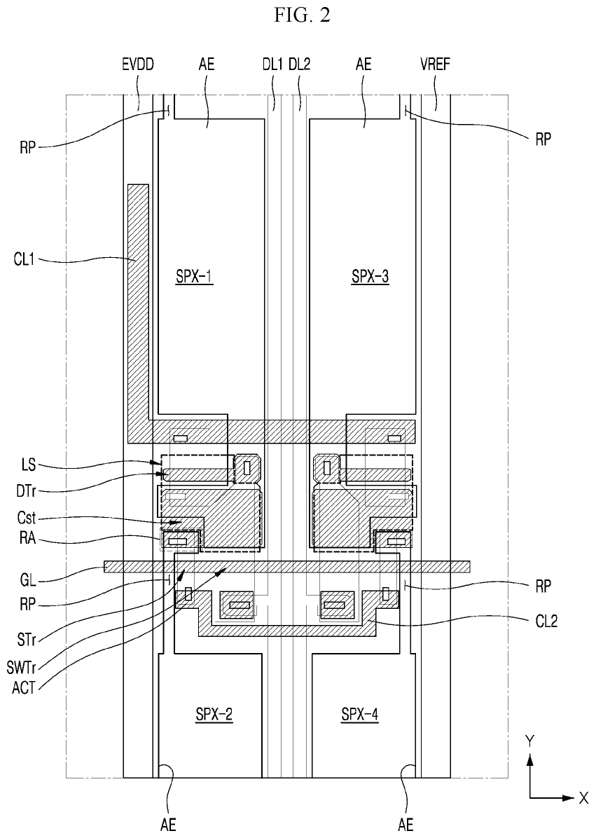

FIG. 2 is a plan view showing a portion of a sub-pixel disposed on the display area of FIG. 1. For example, FIG. 2 shows four sub-pixels disposed adjacent to each other among the plurality of sub-pixels SPA.

Referring to FIGS. 1 and 2, the plurality of sub-pixel SPA may be arranged in the display area AA.

The sub-pixels SPA include a first sub-pixel SPX-1, a second sub-pixel SPX-2, a third sub-pixel SPX-3, and a fourth sub-pixel SPX-4 arranged adjacent to each other in the first and second directions. In an aspect of the present disclosure, the four sub-pixels are illustrated for convenience of illustration. However, the present disclosure is not limited thereto. For example, a plurality of sub-pixels emitting light of different colors from each of the first sub-pixel SPX-1 and the third sub-pixel SPX-3 may be disposed along the X-axis direction. In addition, sub-pixels disposed along the Y-axis direction may emit the same color.

In one aspect of the present disclosure, the first sub-pixel SPX-1 and the third sub-pixel SPX-3 are arranged to be spaced apart from each other in the first direction (the X-axis direction), while the second sub-pixel SPX-2 and the fourth sub-pixel SPX-4 are arranged to be spaced from each other in the first direction (the X-axis direction). The first sub-pixel SPX-1 and the second sub-pixel SPX-2 are arranged to be spaced apart from each other in the Y-axis direction as the second direction, while the third sub-pixel SPX-3 and the fourth sub-pixel SPX-4 are arranged to be spaced apart from each other in the second direction (the Y-axis direction).

Sub-pixels disposed along the Y-axis direction may emit light of the same color. For example, the first sub-pixel SPX-1 and the second sub-pixel SPX-2 may emit the same color each other. Also, the third sub-pixel SPX-1 and the fourth sub-pixel SPX-4 may emit light of the same color each other. Further, sub-pixels disposed along the X-axis direction may emit light of different colors. For example, the first sub-pixel SPX-1 and the third sub-pixel SPX-3 may emit different colors.

Each of the sub-pixels SPX-1, SPX-2, SPX-3, and SPX-4 includes a light-emitting area in which an organic light-emissive layer emitting light is disposed, and a circuit area in which circuit elements for supplying driving current to the organic light-emissive layer are disposed.

The circuit elements may include a driving transistor DTr, a storage capacitor Cst, a sensing transistor STr, and a switching transistor SWTr. The circuit elements constituting the circuit area are disposed in the remaining area except for the light-emitting area.

In an aspect of the present disclosure, the circuit elements constituting the circuit area disposed in the first sub-pixel SPX-1 will be described. The circuit elements constituting the circuit area disposed in each of the second sub-pixel SPX-2, the third sub-pixel SPX-3, or the fourth sub-pixel SPX-4 may have the same configuration as that of the circuit elements of the first sub-pixel SPX-1.

A driving power supply line EVDD is disposed on one side of the first sub-pixel SPX-1 and the second sub-pixel SPX-2. The driving power supply line EVDD may extend along the Y-axis direction as the second direction. The driving power supply line EVDD may supply power voltage via a first connection wiring line CL1.

Data lines DL1 and DL2 are disposed between the first sub-pixel SPX-1 and the third sub-pixel SPX-3 and between the second sub-pixel SPX-2 and the fourth sub-pixel SPX-4. The data lines DL1 and DL2 provide the data signals generated from the data driver 12 to the display area.

The data lines DL1 and DL2 may extend along the Y-axis direction as the second direction. The data lines DL1 and DL2 may include the first data line DL1 disposed on the other side of the first sub-pixel SPX-1, and the second data line DL2 disposed on one side of the third sub-pixel SPX-3. The first data line DL1 is disposed on the other side opposite to one side of the first sub-pixel SPX-1 on which the driving power supply line EVDD is disposed. The first data line DL1 and the second data line DL2 are spaced apart from each other.

A reference power supply line VREF is disposed on the other side of the third sub-pixel SPX-3. The reference power supply line VREF may extend along the Y-axis direction as the second direction.

The gate line GL extends in a direction that intersects the driving power supply line EVDD, the first data line DL1, the second data line DL2 and the reference power supply line VREF which extend in the Y-axis direction. The gate line GL may extend along the X-axis direction. The gate line GL may supply a scan signal to select each horizontal line while the data signals are supplied to each of the sub-pixels SPX-1, SPX-2, SPX-3, and SPX-4 via the first and second data lines DL1 and DL2.

In an aspect of the present disclosure, the first sub-pixel SPX-1 and the third sub-pixel SPX-3 may be commonly connected to the driving power supply line EVDD. The driving transistor DTr switches driving power to be provided to an organic light-emitting element disposed to each of the sub-pixels SPX-1, SPX-2, SPX-3, and SPX-4. In one example, the driving transistor DTr disposed in the first sub-pixel SPX-1 may be electrically connected to the driving power supply line EVDD.

The storage capacitor Cst may be disposed between the driving transistor DTr and the gate line GL. The storage capacitor Cst serves to maintain the light emission of the organic light-emitting element by charging the voltage supplied via the driving power supply line EVDD therein.

The sensing transistor STr may be connected to the reference power supply line VREF that supplies a sensing signal via the second connection wiring line CL2. In an aspect of the present disclosure, the sensing transistor STr may be turned on based on a scan signal provided from the gate line GL. When the sensing transistor is turned on, the sensing signal of the reference power supply line VREF may be provided to the storage capacitor Cst. A gate electrode of the sensing transistor STr may be embodied as a portion of the gate line GL.

The switching transistor SWTr may be electrically connected to the driving transistor Dtr and the data line DL1. When the switching transistor SWTr is turned on, the data voltage supplied via the data line DL1 may be applied to the driving transistor Dtr.

When the driving transistor DTr is turned on, the power supplied from the driving power supply line EVDD is applied to the organic light-emitting element to emit light. Moreover, the storage capacitor Cst may maintain the voltage of the gate electrode of the driving transistor DTr to be constant during the timed duration when the driving transistor DTr is turned on to maintains light emission of the organic light-emitting element.

In an aspect of the present disclosure, each of the sub-pixels SPX-1, SPX-2, SPX-3, and SPX-4 may be configured to include a repair pattern RP for repairing a defective sub-pixel into a normal sub-pixel. For example, the second sub-pixel SPX-2 arranged in the Y-axis downward direction from the first sub-pixel SPX-1 may include the repair pattern RP having a shape extending toward the first sub-pixel SPX-1.

The repair pattern RP may extend to overlap with an electrode of the storage capacitor Cst of the first sub-pixel SPX-1 while a protective layer made of an insulating material is interposed between the repair pattern RP and the electrode. As the repair pattern RP is disposed in a capacitor area where the storage capacitor Cst of the first sub-pixel SPX-1 is disposed, a portion of the capacitor area of the first sub-pixel SPX-1 may be defined as a repair area. The repair pattern RP may have a shape extending from an anode electrode AE of the organic light-emitting element of the second sub-pixel SPX-2. In an aspect of the present disclosure, the repair pattern RP and the anode electrode AE of the second sub-pixel SPX-2 may include the same material and may be formed using the same process.

The fourth sub-pixel SPX-4 arranged in the Y-axis downward direction from the third sub-pixel SPX-3 may include the repair pattern having a shape extending toward the third sub-pixel SPX-3. As the repair pattern of the fourth sub-pixel SPX-4 is disposed in a capacitor area of the third sub-pixel SPX-3, a portion of the capacitor area of the third sub-pixel SPX-3 may be defined as a repair area. The repair pattern may have a shape extending from an anode electrode of the organic light-emitting element of the fourth sub-pixel SPX-4. In an aspect of the present disclosure, the repair pattern and the anode electrode of the fourth sub-pixel SPX-4 may include the same material and may be formed using the same process. In other words, the repair pattern of each sub-pixel and the anode electrode may include the same material and may be formed using the same process.

In addition, in the embodiment of the present specification, the repair pattern of the second sub-pixel SPX-2 and the repair pattern of the fourth sub-pixel SPX-4 have been described for convenience of description, wherein the repair pattern of the second sub-pixel SPX-2 is connected to the first sub-pixel SPX-1, and the repair pattern of the fourth sub-pixel SPX-4 is connected to the third sub-pixel SPX-3. However, it is not limited thereto.

For example, the anode electrode AE of the first sub-pixel SPX-1 may include a repair pattern RP extending in the Y-axis direction. The repair pattern RP of the first sub-pixel SPX-1 may extend to another sub-pixel in the Y-axis upward direction of the first sub-pixel SPX-1 and disposed in the capacitor area of another sub-pixel. Also, the anode electrode AE of the third sub-pixel SPX-3 may include a repair pattern RP extending in the Y-axis direction. The repair pattern RP of the third sub-pixel SPX-3 may extend to another sub-pixel in the Y-axis upward direction of the third sub-pixel SPX-3 and disposed in the capacitor area of another sub-pixel.

In other words, in each sub-pixel of the display panel 100 (see FIG. 1) according to an aspect of the present disclosure, a plurality of repair patterns are disposed to convert a defective sub-pixel into a normal sub-pixel. One of the plurality of repair patterns corresponding to one sub-pixel extends toward another sub-pixel adjacent thereto in the Y-axis direction to be disposed in the capacitor area of another sub-pixel. Accordingly, as the repair area overlap with the capacitor area, a separate repair area is not required in the circuit area of the sub-pixel. Accordingly, the repair pattern of each of the sub-pixels may be continuously connected (e.g., tail bite shape) to each other along the Y-axis direction.

Also, a situation in which the separate repair area is disposed in the circuit area to reduce an area of an opening may be prevented or reduced.

Hereinafter, the capacitor area including the repair area will be described in detail with reference to drawings.

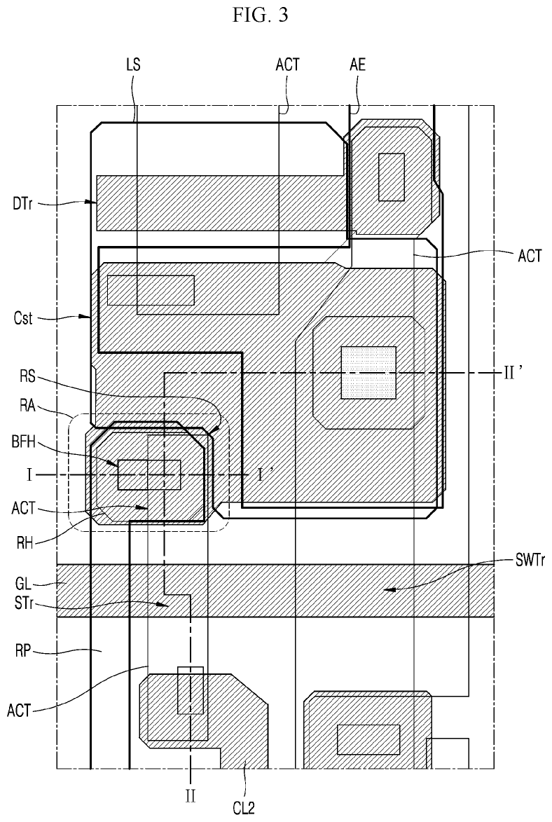

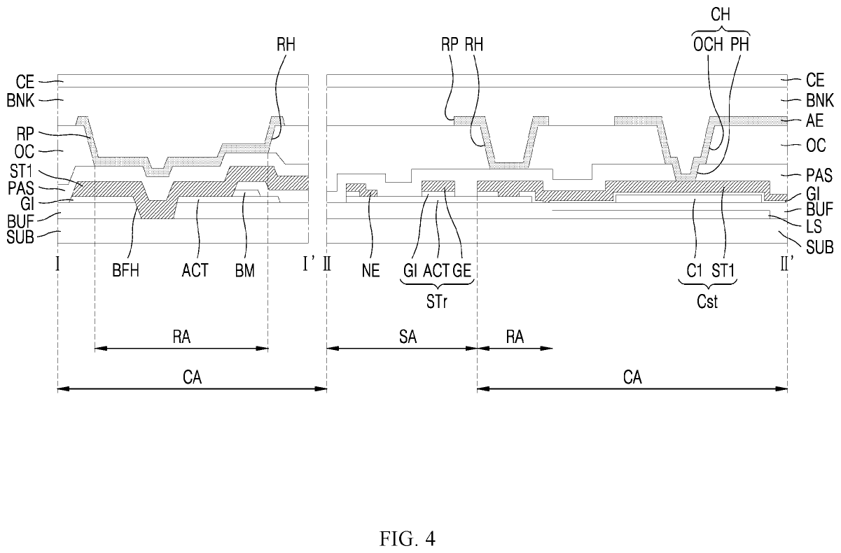

FIG. 3 is an enlarged plan view of a partial area of the circuit area in FIG. 2. FIG. 4 is a cross-sectional view as cut along I-I′ and II-IP of FIG. 3.

Referring to FIGS. 3 and 4, a buffer layer BUF may be disposed on a substrate SUB and in a capacitor area CA including a repair area RA and in a sensing area SA where the sensing transistor STr is disposed. A portion of the buffer layer BUF disposed in the repair area RA may have a buffer hole BFH defined therein. A portion of a surface of the substrate SUB may be exposed through the buffer hole BFH in the repair area RA. The buffer layer BUF may include an insulating material such as silicon oxide or silicon nitride. In one example, in another aspect, the buffer layer BUF may have a flat surface without including the buffer hole BFH.

A light blocking layer LS may be disposed between the substrate SUB and the buffer layer BUF and in a portion of the capacitor area CA except for the repair area RA. The light blocking layer LS may include an opaque metal material. For example, the light blocking layer LS may include an opaque metal material such as molybdenum (Mo), aluminum (Al), titanium (Ti) and copper (Cu), or an alloy thereof.

In a plan view, the light blocking layer LS disposed in the capacitor area CA has a recess RS in which at least one corner portion is recessed inwardly, and thus in the repair area RA, the light blocking layer LS is absent and thus does not overlap with the second electrode ST1 of the capacitor. Then, in the repair area RA which is located outside the recess RS, a portion of the second electrode ST1 of the capacitor is exposed. Accordingly, the light blocking layer LS does not overlap with the repair pattern RP in the repair area RA.

An active layer ACT is disposed on the buffer layer BUF. The active layer ACT disposed in the repair area RA may be disposed on an upper surface of the buffer layer BUF and on one side of the buffer hole BFH and may extend in the second direction, for example, the Y-axis direction. The active layer ACT disposed in the capacitor area CA may extend across the light-blocking layer LS and extend in the Y-axis direction to extend to an area where the driving transistor DTr is disposed. The active layer ACT may include a semiconductor layer. In one example, the active layer ACT may further include a barrier metal layer BM. The semiconductor layer may include at least one of oxide semiconductor materials such as indium gallium zinc oxide (IGZO), and indium zinc oxide (IZO). The barrier metal layer BM may include titanium molybdenum (MoTi).

On the active layer ACT, the second electrode ST1 of the capacitor Cst, a gate electrode GE, and source/drain electrodes NE are disposed. The gate electrode GE is disposed in the sensing area SA, and the source/drain electrodes NE are respectively disposed on both opposing sides of the gate electrode GE interposed therebetween. Accordingly, the sensing transistor STr is disposed in the sensing area SA.

The storage capacitor Cst disposed in the capacitor area CA includes the first electrode C1 and the second electrode ST1. The first electrode C1 and the active layer ACT may be formed in the same process and may be positioned in the same plane. The second electrode ST1, the gate electrode GE and the source/drain electrodes NE may be formed in the same process. A gate insulating film GI is disposed between the first electrode C1 and the second electrode ST1 to serve as a dielectric layer.

As one of the source/drain electrodes NE disposed on one side of the sensing transistor STr is disposed in the capacitor area CA including the repair area RA, one of the source/drain electrodes NE may be electrically connected to the capacitor area CA. The other of the source/drain electrodes NE disposed on the other side of the sensing transistor STr may be electrically connected to the reference power supply line VREF (see FIG. 2) via the second connection wiring line CL2.

A gate insulating film GI may be positioned between the gate electrode GE and the active layer ACT and in the sensing area SA. The gate insulating film GI made of a dielectric material may be disposed between the second electrode ST1 and the active layer ACT in the capacitor area CA. In an area where the gate insulating film GI is not disposed, the second electrode ST1 may be disposed to be in contact with an exposed surface of the active layer ACT.

Moreover, in the repair area RA, the second electrode ST1 fills an entirety of the buffer hole BFH defined in the buffer layer BUF and extends to contact an exposed surface of the active layer ACT disposed on an upper surface of the buffer layer BUF disposed on one side of the buffer hole BFH.

A protective layer PAS is disposed on the substrate SUB including the second electrode ST1. The protective layer PAS may be disposed in the sensing area SA, the repair area RA, and the capacitor area CA. The protective layer PAS may include an inorganic insulating material such as silicon oxide (SiOx). The protective layer PAS may have a sufficient thickness to cover an entirety of surfaces of the second electrode ST1, and the source/drain electrodes NE and the gate electrode GE of the sensing transistor STr.

The protective layer PAS may have a first contact-hole PH defined therein extending through the protective layer PAS in the capacitor area CA to expose a portion of a surface of the second electrode ST1.

A planarization film OC is disposed on the protective layer PAS. The planarization film OC may have a sufficient thickness to planarize a surface on the substrate SUB while serving to protect the underlying elements. The planarization film OC may include an organic insulating material. In one example, the planarization film OC may include a photoactive compound (PAC).

The planarization film OC may have a capacitor contact-hole CH defined therein in the capacitor area CA and may have a repair hole RH defined therein in the repair area RA. The capacitor contact-hole CH may include a first contact-hole PH and a second contact-hole OCH. The second contact-hole OCH may overlap with the first contact-hole PH while extending through the planarization film OC. A portion of the surface of the second electrode ST1 may be exposed thorough the capacitor contact-hole CH including the first contact-hole PH and the second contact-hole OCH.

The repair hole RH may extend through the planarization film OC to expose a portion of a surface of the protective layer PAS. As described above, the repair area RA where the repair hole RH is disposed overlap with the recess RS of the light-blocking layer LS disposed in the capacitor area CA. Accordingly, the light-blocking layer LS is not disposed under the repair hole RH, but the second electrode ST1 is disposed under the repair hole RH.

The anode electrode AE and the repair pattern RP are disposed on the planarization film OC. The anode electrode AE may be disposed along an exposed surface of the capacitor contact-hole CH defined in the planarization film OC, and may extend on and along an upper surface of the planarization film OC and may extend into the light-emitting area. The repair pattern RP may be disposed along an exposed surface of the repair hole RH defined in the planarization film OC in the repair area RA, and may extend along and on the upper surface of the planarization film OC. The anode electrode AE and the repair pattern RP may include the same material and may be formed using the same process. In one example, the anode electrode AE and the repair pattern RP may be composed of a transparent metal oxide such as indium-tin-oxide (ITO) or indium-zinc-oxide (IZO). The anode electrode AE may be referred to as a pixel electrode.

The repair pattern RP is disposed in a position overlapping with the second electrode ST1 while the protective layer PAS is interposed therebetween. The repair pattern RP may have a shape extending from the anode electrode AE of the second sub-pixel SPX-2 disposed downwardly in the Y-axis direction of the first sub-pixel SPX-1. Accordingly, the repair area disposed in the capacitor area CA of the first sub-pixel SPX-1 may be defined as the repair area RA of the second sub-pixel SPX-2.

A bank BNK that have a bank hole defined therein is disposed on the anode electrode AE and the repair pattern RP. The bank hole may expose a portion of a surface of the anode electrode AE to define the light-emitting area. The bank BNK serves to define each sub-pixel. Moreover, the bank BNK serves to prevent or reduce light beams of different colors output from adjacent sub-pixels from being mixed with each other. The bank BNK may be composed of an organic insulating film or an inorganic insulating film.

An organic light-emissive layer (not shown) and the cathode electrode CE are sequentially disposed on the bank BNK. The organic light-emissive layer is made of an organic material emitting white light, and a color filter disposed thereon may render a color. However, the present disclosure is not limited thereto. The cathode electrode CE may commonly contact adjacent sub-pixels on the display area AA to apply a voltage thereto. The cathode electrode CE may be referred to as a common electrode.

As described above, the repair pattern RP may be positioned to overlap with the second electrode ST1 while the protective layer PAS is interposed therebetween. The repair pattern RP is electrically insulated from the second electrode ST1 via the protective layer PAS before laser irradiation to the repair area RA when a defect occurs in the corresponding sub-pixel. Then, when a defect occurs in the corresponding sub-pixel and thus the laser is irradiated in a direction from a rear surface of the substrate SUB to the repair area RA, the second electrode ST1 absorbs the energy of the laser and thus a phase thereof transitions to liquid. Then, the metal material of the second electrode ST1 expands to form a protrusion extending through the protective layer PAS.

The protrusion of the second electrode ST1 extending through the protective layer PAS may contact and be electrically connected to the repair pattern RP. When the second electrode ST1 and the repair pattern RP come into contact with each other and are electrically connected to each other, the repair pattern RP may be electrically connected to the sensing transistor STr via the active layer ACT in contact with the second electrode ST1 of the capacitor of the first sub-pixel SPX-1. Then, the repair pattern RP is electrically connected to the driving transistor DTr of the first sub-pixel SPX-1 via the second electrode ST1 of the capacitor of the first sub-pixel SPX-1. Therefore, the driving power output from the driving transistor DTr is supplied to the second sub-pixel SPX-2 via the repair pattern RP so that the organic light-emitting element of the second sub-pixel SPX-2 may emit light.

In other words, when a defect occurs in the second sub-pixel SPX-2, the repair pattern RP of the second sub-pixel SPX-2 may be electrically connected to the normally operating first sub-pixel SPX-1, such that the second sub-pixel SPX-2 may be repaired to emit light. Accordingly, the first sub-pixel SPX-1 and the second sub-pixel SPX-2 may emit light of the same color.

According to an aspect of the present disclosure, the repair area RA in which the repair pattern RP is disposed overlap with the capacitor area CA. Accordingly, a separate space for the repair pattern may not be disposed in the circuit area. Therefore, a space margin equal to the repair area may be secured as a space for securing the aperture ratio. Accordingly, an aperture ratio important in a display device implementing high-definition screen and ultra-high resolution screen may be improved. Moreover, improving the aperture ratio may allow a lifetime of the organic light-emitting element to be improved.

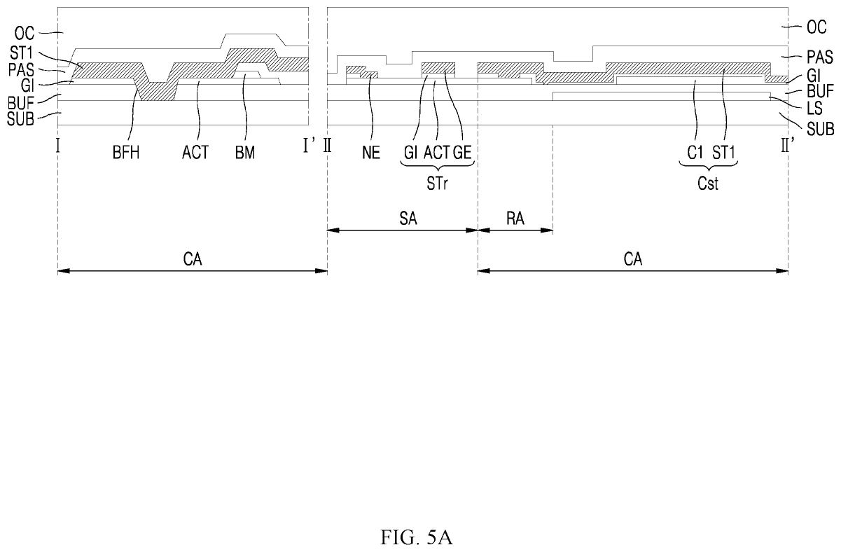

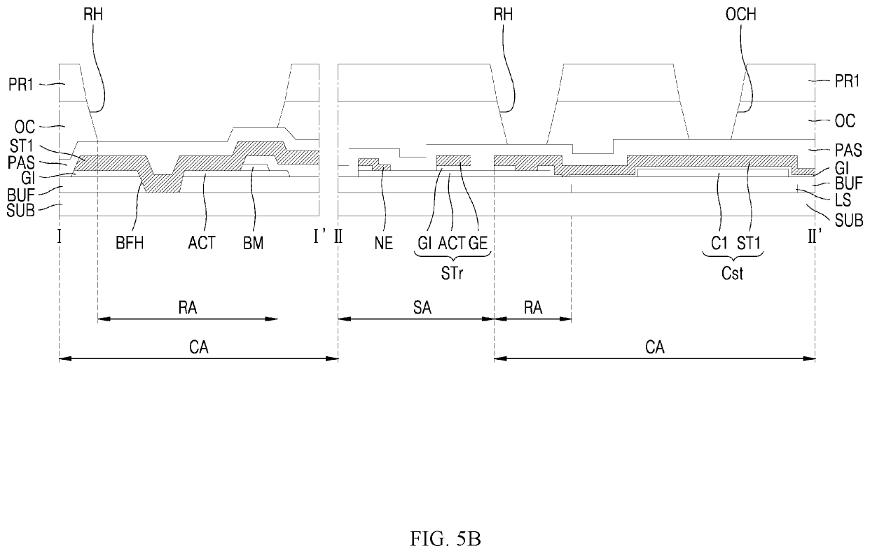

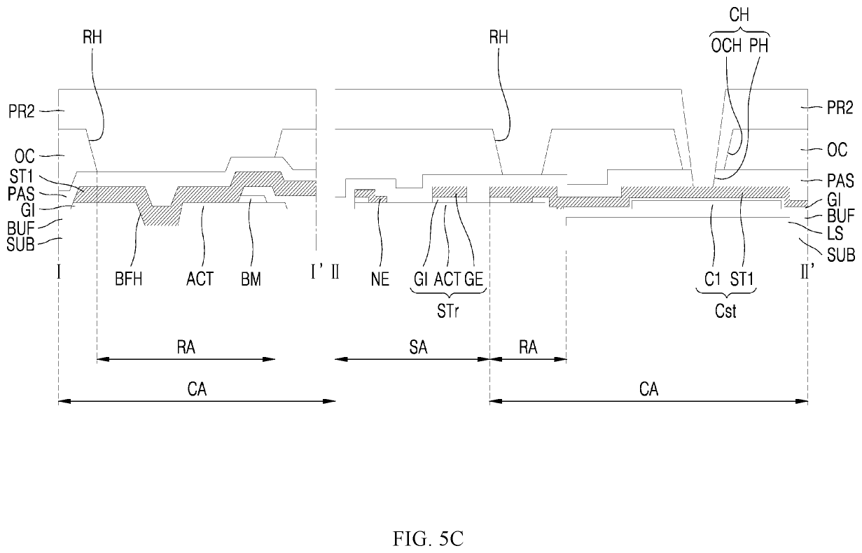

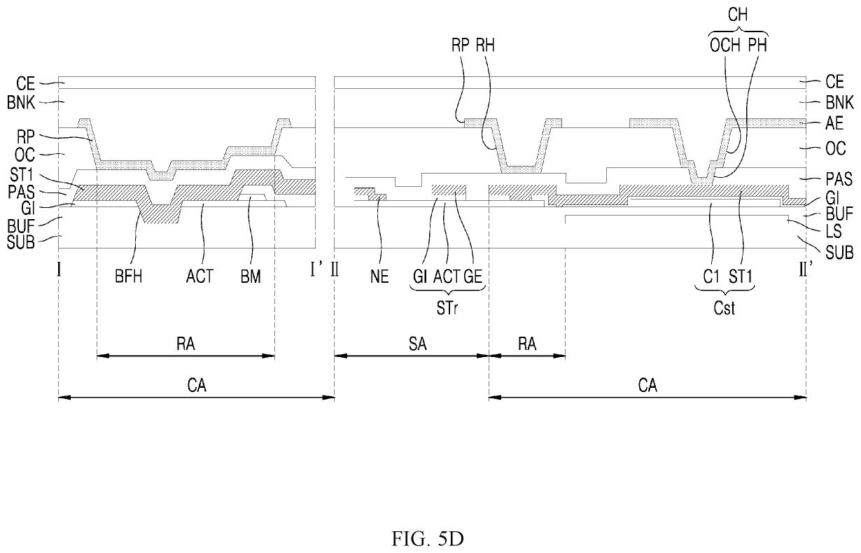

FIG. 5A to FIG. 5E are diagrams for illustrating a method for manufacturing a display device according to an aspect of the present disclosure. In this regard, the same or similar components as or to those in FIG. 1 to FIG. 4 will be briefly described.

Referring to FIG. 5A, the buffer layer BUF may be disposed on the substrate SUB. The substrate SUB may include the sensing area SA where the sensing transistor STr is disposed, the capacitor area CA, and the repair area RA. The buffer hole BFH may be defined in the buffer layer BUF in the repair area RA. The buffer hole BFH exposes a portion of a surface of the substrate SUB in the repair area RA.

In the capacitor area CA, the light-blocking layer LS is disposed between the substrate SUB and the buffer layer BUF. The light-blocking layer LS is disposed in a portion of the capacitor area CA except for the repair area RA included in the capacitor area CA. Accordingly, the light-blocking layer LS has the recess RS in which at least one corner portion is recessed inwardly in the plan view. This recess RS may overlap with the repair area RA.

The sensing transistor STr is disposed in the sensing area SA, and the second electrode ST1 of the capacitor is disposed in the capacitor area CA. The sensing transistor STr includes the source/drain electrodes NE respectively disposed on both opposing sides of the gate electrode GE while the gate electrode GE is interposed therebetween. The gate electrode GE and the source/drain electrodes NE may be made of the same material and may be formed in the same process. The active layer ACT may be disposed under the gate electrode GE and the source/drain electrode NE.

One of the source/drain electrodes NE disposed on one side of the sensing transistor STr may be disposed in the capacitor area CA including the repair area RA and may be electrically connected to the storage capacitor. The active layer ACT and the gate insulating film GI made of a dielectric material may be disposed under the second electrode ST1 in the capacitor area CA.

Next, the protective layer PAS covering the sensing transistor STr and the storage capacitor is formed, and the planarization film OC is formed on the protective layer PAS.

Referring to FIG. 5B, a first patterning process of patterning the planarization film OC using the first mask pattern PR1 is performed to form the repair hole RH and the second contact-hole OCH. The process of patterning the planarization film OC may be performed using a photo process. Specifically, a photoresist material is applied on the planarization film OC, and exposure and development processes are performed to form the first mask pattern PR1 having an opening exposing a portion of a surface of the planarization film OC.

Next, an etching process of etching a portion of the planarization film OC exposed through the opening is performed using the first mask pattern PR1 as an etching mask. The etching process may be performed such that the etchant passes through the planarization film OC to a point at which a surface of the underlying protective layer PAS is exposed. The etching process may be performed using a dry etching or wet etching scheme. When the surface of the protective layer PAS at the position corresponding to the opening of the first mask pattern PR1 is exposed, the etching process is stopped and the first mask pattern PR1 is removed.

Then, in the repair area RA, the repair hole RH extending through the planarization film OC while exposing the surface of the protective layer PAS may be formed. In the capacitor area CA, the second contact-hole OCH extending through the planarization film OC may be formed.

Referring to FIG. 5C, a second patterning process of patterning the protective layer PAS of the capacitor area CA is performed using a second mask pattern PR2. A process of patterning the protective layer PAS may be performed using a photo process. Specifically, a photoresist material is applied on the planarization film OC having the repair hole RH defined therein to expose the surface of the protective layer PAS. Subsequently, exposure and development processes are performed to form the second mask pattern PR2 having an opening exposing a portion of the surface of the protective layer PAS in the capacitor area CA. In the repair area RA, a surface of the protective layer PAS exposed through the first contact-hole PH may be entirely covered with the second mask pattern PR2.

Next, the protective layer PAS of the capacitor area CA exposed through the opening is etched using the second mask pattern PR2 as an etch mask. The etching process may proceed to a point where the surface of the second electrode ST1 of capacitor area CA is exposed. The etching process may be performed using a dry etching scheme. When a portion of a surface of the second electrode ST1 corresponding to the opening of the second mask pattern PR2 is exposed, the etching process is stopped and the second mask pattern PR2 is removed.

Then, in the repair area RA, the repair hole RH extending through the planarization film OC while exposing the surface of the protective layer PAS may be formed. In the capacitor area CA, the capacitor contact-hole CH extending through the planarization film OC and the protective layer PAS, and including the second contact-hole OCH and the first contact-hole PH may be formed.

Next, referring to FIG. 5D, the anode electrode AE and the repair pattern RP are formed on the planarization film OC. The anode electrode AE may be disposed along and on the exposed surface of the capacitor contact-hole CH disposed in the planarization film OC, and may extend on and along the upper surface of the planarization film OC and may be disposed in the light-emitting area. The repair pattern RP may be disposed along and on the exposed surface of the repair hole RH disposed in the planarization film OC of the repair area RA, and may extend to cover a portion of the upper surface of the planarization film OC.

The anode electrode AE and the repair pattern RP may include the same material and may be formed using the same process so that the anode electrode AE and the repair pattern RP are disposed in the same plane. For example, each of the anode electrode AE and the repair pattern RP may include a transparent metal oxide such as indium-tin-oxide (ITO) or indium-zinc-oxide (IZO).

The repair pattern RP may extend from the anode electrode AE of the second sub-pixel SPX-2 disposed downwardly in the Y-axis direction of the first sub-pixel SPX-1. Accordingly, the repair area disposed in the capacitor area CA of the first sub-pixel SPX-1 may act as the repair area RA of the second sub-pixel SPX-2.

Subsequently, the bank BNK including the bank hole may be formed on the anode electrode AE and the repair pattern RE. The bank BNK may define the light-emitting area via the bank hole exposing a portion of the surface of the anode electrode AE.

The organic light-emissive layer (not shown) and the cathode electrode CE are sequentially formed on the bank BNK. The organic light-emissive layer may be disposed between the anode electrode AE and the cathode electrode CE in the light-emitting area. The organic light-emissive layer may be made of an organic material emitting white light, and a color filter disposed thereon may render a color. However, the present disclosure is not limited thereto. The cathode electrode CE may commonly contact sub-pixels disposed adjacent to each other in the display area AA and may apply a voltage thereto.

In the repair area RA, the repair pattern RP may be disposed in contact with a portion of the protective layer PAS exposed through the repair hole RH extending through the planarization film OC. The repair pattern RP may be positioned to overlap with the second electrode ST1 while the protective layer PAS is interposed therebetween.

Defects such as the sub-pixel not emitting light or acting as a bright spot may occur due to causes such as foreign substances generated in the process of forming the display device in the above-described process.

Referring to FIG. 5E, a repair process performed when the defect occurs in a sub-pixel will be described.

Referring to FIG. 5E, the repair pattern RP overlap with the second electrode ST1 while the protective layer PAS is interposed therebetween. Before the laser irradiation is performed for the repair process due to the defect in the sub-pixel in the repair area RA, the repair pattern RP is electrically insulated from the second electrode ST1 via the protective layer PAS.

When a defect occurs in the corresponding sub-pixel and thus the laser L is irradiated in a direction from the rear surface of the substrate SUB to the repair area RA, the second electrode ST1 absorbs the energy of the laser such that a phase thereof transitions to liquid. Then, a partial area of the second electrode ST1 irradiated with the laser expands to form a protrusion PT extending through the protective layer PAS. As the protrusion PT extending through the protective layer PAS comes into contact with the repair pattern RP, the second electrode ST1 and the repair pattern RP may be electrically connected to each other.

When the second electrode ST1 and the repair pattern RP are electrically connected to each other, the repair pattern RP may be electrically connected to the sensing transistor STr via the active layer ACT in contact with the second electrode ST1 of the first sub-pixel SPX-1. Then, the repair pattern RP is electrically connected to the driving transistor Dtr of the first sub-pixel SPX-1 via the second electrode ST1 of the capacitor of the first sub-pixel SPX-1. The repair pattern RP has a shape extending from the anode electrode AE of the second sub-pixel SPX-2. In other words, the repair pattern RP and the anode electrode AE of the second sub-pixel SPX-2 may be integrally formed with each other. Accordingly, the driving power output from the driving transistor DTr of the first sub-pixel SPX-1 may be supplied to the organic light-emitting element of the second sub-pixel SPX-2 via the repair pattern RP.

Accordingly, when a defect occurs in the second sub-pixel SPX-2, the repair pattern RP of the second sub-pixel SPX-2 may be electrically connected to the first sub-pixel SPX-1 as a normal sub-pixel, so that the second sub-pixel SPX-2 may emit light normally.

In one example, the display device according to an aspect of the present disclosure may reduce the laser output energy (Power, W) applied to the repair process.

The output energy of the laser requires a larger output energy as a thickness of a target layer to which the laser is irradiated is larger. As a magnitude of the output energy of the laser increases, damage occurs to the surrounding elements. This will be described with reference to the drawings below.

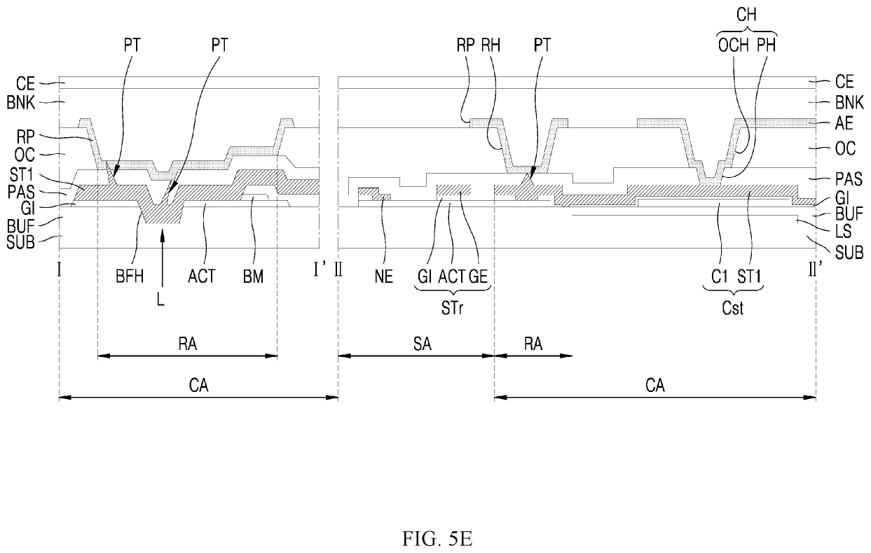

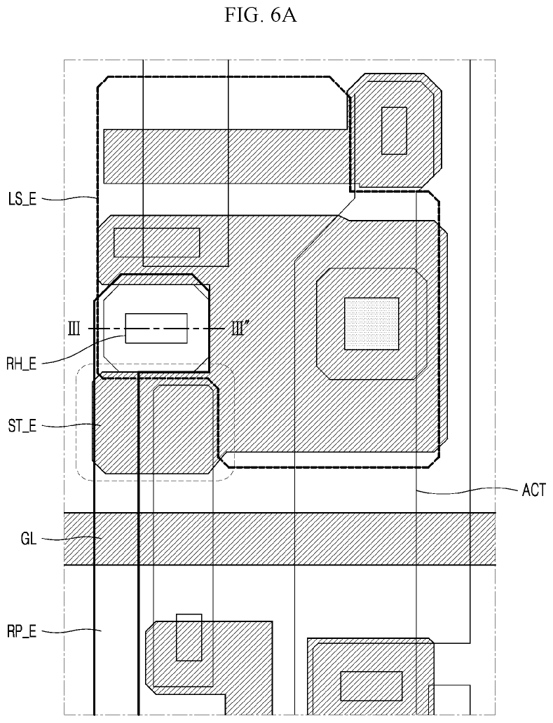

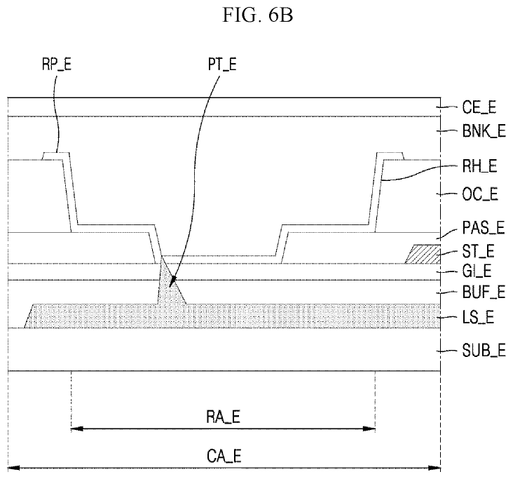

FIG. 6A to FIG. 6C are diagrams for illustrating the repair process according to Comparative Example.

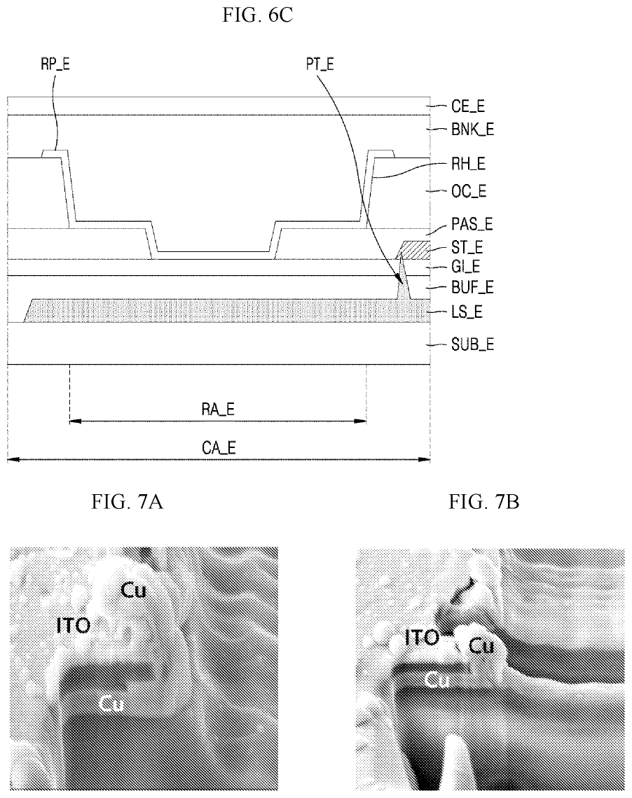

In this regard, FIG. 6A is a plan view showing the repair area of the display device according to Comparative Example. FIG. 6B and FIG. 6C are cross-sectional views showing the results of the repair process on the repair area as cut in direction of FIG. 6A. FIGS. 7A and 7B are images showing repair results based on laser output energy levels.

Referring to FIG. 6A and FIG. 6B, in the display device according to the Comparative Example, a light blocking film LS_E is disposed on a substrate SUB E and in a capacitor area CA_E. In this regard, the light blocking film LS_E extends to a repair area RA_E disposed in the capacitor area CA_E.

A buffer layer BUF_E and a gate insulating film GI_E are disposed on the light blocking layer LS_E. A protective layer PAS_E and a planarization film OC_E are disposed on the gate insulating film GI_E. In the capacitor area CA_E, a capacitor electrode ST_E is disposed on the gate insulating film GI_E. The capacitor electrode ST_E is disposed in a portion of the capacitor area CAE excluding the repair area RA_E. Accordingly, referring to FIG. 6A, the capacitor electrode ST_E may have a shape surrounding three sides of the repair area RA_E.

In the repair area RA_E, a repair hole RH_E extending through the planarization film OC_E and the protective layer PAS_E may be disposed. The repair hole RH_E exposes a portion of a surface of the gate insulating film GI_E. The repair pattern RP_E is disposed along and on an exposed surface of the repair hole RH_E and extends along and on an upper surface of the planarization film OC_E.

Referring back to FIG. 6B, in performing a repair process of connecting the light blocking film LS_E to the repair pattern RP_E, a stack of the buffer layer BUF_E and the gate insulating film GI_E is disposed between the light blocking film LS_E and the repair pattern RP_E.

In this case, to form a protrusion PT_E as a conductive material of the light blocking film LS_E extending through the stack of the multiple layers to be connected to the repair pattern RP_E, the laser requires a large output energy level. For example, when the multiple layers including the buffer layer BUF_E and the gate insulating film GI_E are disposed between the repair pattern RP_E and the light blocking film LS_E, the stack of the multiple layers may have a thickness of at least 5800 Å. In this case, the laser should be irradiated at an output energy level higher than at least 500 W so that the protrusion PT_E of the light blocking film LS_E may extend through the multiple layers to be connected to the repair pattern RP_E.

However, when the laser is irradiated at an output energy level greater than 500 W, damage to surrounding elements may occur, which may act as another cause of defects.

Moreover, when the repair process is performed such that the light blocking film LS_E extends to the repair area RA_E, the repair process may fail because the light blocking film LS_E is not properly connected to the repair pattern RP_E. For example, as shown in FIG. 6C, a connection defect A may occur in which the light blocking film LS_E is connected to a portion of the capacitor electrode ST_E disposed outside the repair area RA_E.

As the capacitor electrode ST_E is disposed to surround the three sides of the repair hole RH_E, the connection defect A may occur adjacent to a side of the repair hole RH_E adjacent to the capacitor electrode ST_E. In this case, the driving current is not provided to the defective sub-pixel, such that the repair process has failed.

In contrast, in an aspect according to the present disclosure, the second electrode ST1 is disposed in the repair area RA, and only a single layer structure composed only of the protective layer PAS is formed between the repair pattern RP and the second electrode ST1. As the protective layer PAS is formed to have a thickness of 3500 Å, the repair process may be reliably performed even when a relatively small laser output energy level is applied.

For example, referring to FIGS. 7A and 7B, it may be identified that both when the repair process is performed by irradiating the laser at an output energy level of 350 W (FIG. 7A), and when the repair process is performed by irradiating the laser at an output energy level of 400 W (FIG. 7B), copper (Cu) as a constituting material of the second electrode ST1 is melted to be connected to indium-tin-oxide (ITO) as a material constituting the anode electrode AE. Accordingly, the damage to surrounding elements by the laser may be prevented or reduced compared to the case of proceeding with the repair process by irradiating the laser at the output energy level greater than at least 500 W. Moreover, when the laser is irradiated at an output energy level smaller than 350 W, the copper Cu constituting the second electrode ST1 may not be melted and thus may not be connected to the anode electrode AE. Accordingly, the laser may irradiate at an output energy level greater than 350 W. In one example, the laser irradiated in the aspect of the present disclosure may have a wavelength of 532 nm.

Moreover, as the second electrode ST1 of the capacitor area CA extends to the repair area RA, the light-blocking layer LS is not disposed under the repair hole RH, and the second electrode ST1 is disposed under the repair hole RH. Accordingly, even when an irradiation position of the laser is misaligned with respect to the repair hole RH, the second electrode ST1 and the repair pattern RP may be connected to each other. Accordingly, the driving power may be supplied to the defective sub-pixel, such that the failure of the repair process may be prevented or reduced.

In one example, the mobility characteristics of the element may be further improved by increasing an area size of the active layer ACT of the sensing transistor STr disposed to overlap with the repair area RA.

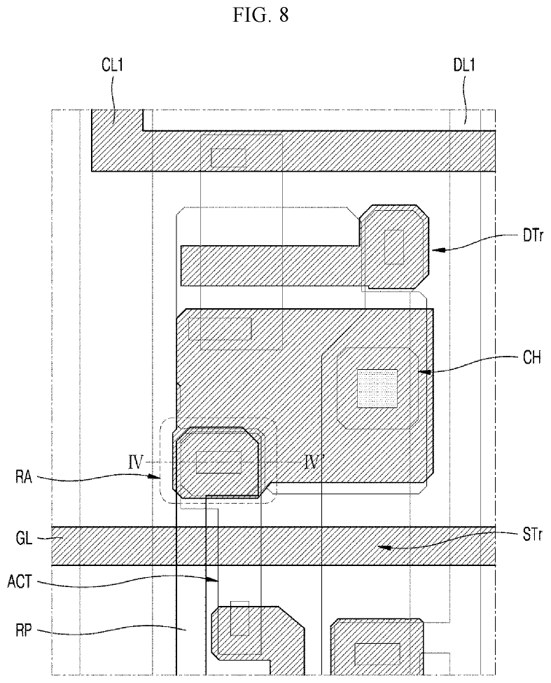

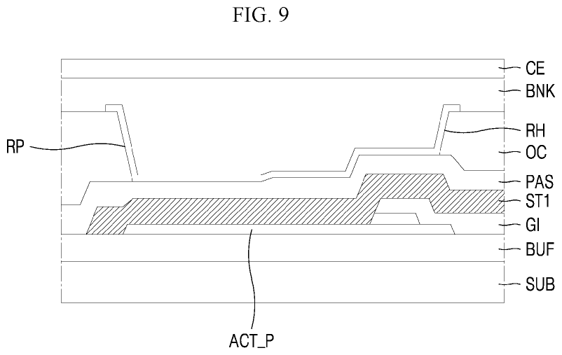

FIG. 8 is a plan view showing a display device according to another aspect of the present disclosure. FIG. 9 is a cross-sectional view as cut along IV-IV′ of FIG. 8. In this regard, FIG. 8 and FIG. 9 have the same components as those in FIG. 1 to FIG. 4 except for the active layer ACT of the sensing transistor STr. Accordingly, only differences therebetween will be described.

Referring to FIG. 8 and FIG. 9, the display device according to another aspect of the present disclosure includes the capacitor area CA including the repair area RA where the source/drain electrodes NE of the sensing transistor STr are disposed. The buffer layer BUF may be disposed on the substrate SUB and in the capacitor area CA. The buffer layer BUF may include an insulating material such as silicon oxide or silicon nitride.

The active layer ACT is disposed on the buffer layer BUF and in the repair area RA. The active layer ACT may include a semiconductor layer. In one example, the active layer ACT may further include the barrier metal layer BM. The semiconductor layer may include at least one of oxide semiconductor materials such as indium gallium zinc oxide (IGZO) and indium zinc oxide (IZO). The barrier metal layer may include titanium molybdenum (MoTi).

On the active layer ACT, the second electrode ST1, the gate electrode GE, and the source/drain electrodes NE are disposed.

The protective layer PAS is disposed on the substrate SUB including the second electrode ST1. The protective layer PAS may be disposed on the sensing area SA, the repair area RA, and the capacitor area CA. The protective layer PAS may include an inorganic insulating material such as silicon oxide (SiOx).

On the protective layer PAS, the planarization film OC having the repair hole RH defined therein is disposed. The planarization film OC may have a sufficient thickness to planarize the surface on the substrate SUB while serving to protect the underlying elements.

The repair hole RH may extend through the planarization film OC to expose a portion of a surface of the protective layer PAS. As described above, the repair area RA where the repair hole RH is disposed to overlap with the recess RS of the light-blocking layer LS disposed in the capacitor area CA. Accordingly, the light-blocking layer LS is not disposed under the repair hole RH, and the second electrode ST1 is disposed under the repair hole RH.

The repair pattern RP is disposed on and along the exposed surface of the repair hole RH defined in the planarization film OC. The repair pattern RP may extend along and on the upper surface of planarization film OC. The repair pattern RP may be made of a transparent metal oxide such as indium-tin-oxide (ITO) and indium-zinc-oxide (IZO).

The active layer ACT_P disposed in the repair area RA may have an area size at least equal to or larger than that of the repair hole RH. Since light in a laser wavelength range transmits through the semiconductor layer of the active layer ACT_P, the active layer ACT_P may be formed under the repair hole RH to overlap with the second electrode ST1. When the active layer ACT_P of the sensing transistor STr is formed to have an area size at least equal to or larger than an area size of the repair hole RH, an area size of an area where the second electrode ST1 disposed under the protective layer PAS and the active layer ACT_P of the sensing transistor STr overlap with each other increases.

When the area size of the area in which the second electrode ST1 and the active layer ACT_P of the sensing transistor STr overlap with each other increases, a contact resistance between the second electrode ST1 and the active layer ACT_P of the sensing transistor STr decreases such that the mobility characteristics of the element may be stabilized. In other words, when the driving power is provided to the defective sub-pixel via the repair pattern RP, the resistance may be further reduced, so that the driving signal may be delivered more easily thereto.

In one example, when the sensing transistor is electrically connected to the storage capacitor, and the second electrode of the storage capacitor is disposed under the repair pattern so that the repair pattern is electrically connected to the second electrode of the storage capacitor, the repair area may be disposed in various locations on the capacitor area.

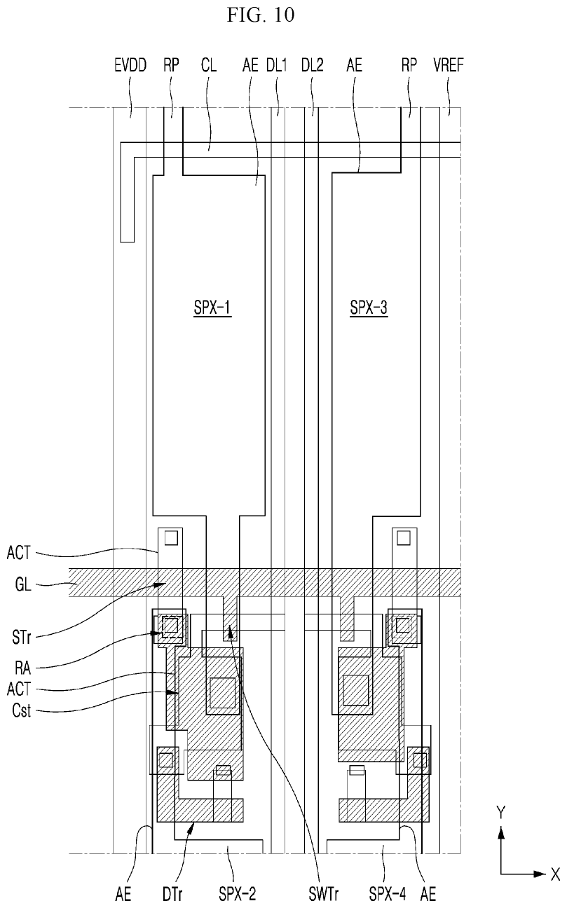

FIG. 10 is a plan view showing a display device according to still another aspect of the present disclosure. In this regard, components identical or similar to those of FIG. 1 to FIG. 4 have the same reference numerals and will be briefly described.

Referring to FIG. 10, the display device includes the first sub-pixel SPX-1, the second sub-pixel SPX-2, the third sub-pixel SPX-3, and the fourth sub-pixel SPX-4 arranged adjacent to each other. In an aspect of the present disclosure, the four sub-pixels are illustrated for convenience of illustration. However, the present disclosure is not limited thereto.

Each of the sub-pixels SPX-1, SPX-2, SPX-3, and SPX-4 has a light-emitting area in which an organic light-emissive layer emitting light is disposed, and a circuit area in which circuit elements for supplying the driving current to the organic light-emissive layer are disposed. The circuit element may include a driving transistor DTr, a storage capacitor Cst, a sensing transistor STr, and a switching transistor SWTr. The circuit elements constituting the circuit area are disposed in the remaining area except for the light-emitting area.

A driving power supply line EVDD is disposed on one side of the first sub-pixel SPX-1 and the second sub-pixel SPX-2. Data lines DL1 and DL2 are disposed between the first sub-pixel SPX-1 and the third sub-pixel SPX-3 and between the second sub-pixel SPX-2 and the fourth sub-pixel SPX-4. A reference power supply line VREF is disposed on the other side of the third sub-pixel SPX-3. The reference power supply line VREF may extend along the Y-axis direction as the second direction.

The gate line GL extends in a direction that intersects the driving power supply line EVDD, the first data line DL1, the second data line DL2 and the reference power supply line VREF which extend in the Y-axis direction. The gate line GL may extend along the X-axis direction. The gate line GL may be disposed adjacent to the light-emitting area of each of the first sub-pixel SPX-1 and the third sub-pixel SPX-3.

The storage capacitor Cst may be disposed downwardly in the Y-axis direction of the gate line GL. Accordingly, the gate line GL may be disposed between the light-emitting area and the storage capacitor Cst. The active layer ACT of the sensing transistor STr extends in the Y-axis direction intersecting the gate line GL. A gate electrode of the sensing transistor STr may be embodied as a portion of the gate line GL. In another example, the gate electrode of the sensing transistor STr may be embodied as a portion branched from the gate line GL.

One end of the active layer ACT of the sensing transistor STr may extend toward the storage capacitor Cst to be electrically connected to the storage capacitor Cst.

The anode electrode AE is disposed in the light-emitting area of each of the sub-pixels SPX-1, SPX-2, SPX-3, and SPX-4. Moreover, each of the sub-pixels SPX-1, SPX-2, SPX-3, and SPX-4 may be configured to include the repair pattern RP for converting the defective sub-pixel into the normal sub-pixel. The repair pattern RP of one sub-pixel may have a shape extending from the anode electrode AE of another sub-pixel adjacent thereto. For example, the repair pattern RP may have a shape extending from one end of the anode electrode AE of the second sub-pixel SPX-2 arranged in the Y-axis direction from the first sub-pixel SPX-1 toward the first sub-pixel SPX-1. In one example, the repair pattern RP of one sub-pixel may be formed to extend from an upper left or right end of the anode electrode AE toward another sub-pixel adjacent thereto in the Y-axis direction.

The driving transistor DTr is electrically connected to the storage capacitor Cst. The storage capacitor Cst may be disposed between and connected to the driving transistor DTr and the gate line GL. The storage capacitor Cst may be electrically connected, in at least one corner portion thereof, to one end of the active layer ACT of the sensing transistor STr. The repair area RA including the repair hole RH may be disposed in the corner portion of the storage capacitor Cst electrically connected to one end of the active layer ACT of the sensing transistor STr.

In another aspect of the present disclosure, each of the sub-pixels SPX-1, SPX-2, SPX-3, and SPX-4 includes the repair pattern for converting a defective sub-pixel into a normal sub-pixel. For example, the second sub-pixel SPX-2 arranged in the Y-axis direction from the first sub-pixel SPX-1 may include the repair pattern RP having a shape extending toward the first sub-pixel SPX-1.

The repair pattern RP may have a shape extending from the anode electrode AE of the organic light-emitting element of the second sub-pixel SPX-2. The repair pattern RP may extend from a corner of one side of the anode electrode AE of the second sub-pixel SPX-2 to be disposed in the repair hole RH disposed in the storage capacitor Cst. For example, the repair pattern RP may extend from the left upper or right upper corner of the anode electrode AE. Accordingly, the sensing transistor STr is electrically connected to the storage capacitor Cst, and the repair pattern RP is electrically connected to the sensing transistor STr in the repair hole RH. In this case, the repair area RA may be disposed at various positions on the capacitor area.

According to an aspect of the present disclosure, the repair area may be disposed in the capacitor area, such that a separate space for the repair pattern may not be disposed in the circuit area. Accordingly, a space margin equal to the space for forming the repair pattern may be secured, such that the aperture ratio may be improved. Therefore, the repair process may be performed while securing the aperture ratio even in high-definition or ultra-high-definition models.

Moreover, reducing the thickness of the layer disposed between the repair pattern and the second electrode may allow the repair process to be reliably performed even using the laser at a relatively small laser output energy level. This may prevent or reduce the elements around the repair pattern from being damaged by the laser, thereby improving the reliability of the display device.

In addition, the repair failure may be prevented or reduced even when the laser irradiation position is misaligned with a target position.

Moreover, increasing the area size of the area in which the active layer overlap with the repair area may allow the electrical resistance of the sensing transistor to be reduced, such that the mobility characteristics of the element may be stabilized.

Although the aspects of the present disclosure have been described in more detail with reference to the accompanying drawings, the present disclosure is not necessarily limited to these aspects, and may be modified in a various manner within the scope of the technical spirit of the present disclosure. Accordingly, the aspects as disclosed in the present disclosure are intended to describe rather than limit the technical idea of the present disclosure, and the scope of the technical idea of the present disclosure is not limited by these aspects. Therefore, it should be understood that the aspects described above are not restrictive but illustrative in all respects.

It will be apparent to those skilled in the art that various modifications and variations can be made in the display device and the method for repairing the display device of the present disclosure without departing from the spirit or scope of the aspects. Thus, it is intended that the present disclosure covers the modifications and variations of the aspects provided they come within the scope of the appended claims and their equivalents.

What is claimed is:

1. A display device comprising:
a substrate;
a plurality of sub-pixels disposed on the substrate and arranged in a first direction and a second direction crossing the first direction;
a plurality of anode electrodes included in each of the sub-pixels; and
a storage capacitor disposed under and overlapping with each of the anode electrodes,
wherein the plurality of anode electrodes include a first anode electrode of a first sub-pixel of the plurality of sub-pixels, and a second anode electrode of a second sub-pixel of the plurality of sub-pixels disposed adjacent to the first sub-pixel along the second direction, and
wherein the second anode electrode includes a repair pattern extending along the second direction toward the first sub-pixel and overlaps with the storage capacitor of the first sub-pixel.

2. The display device of claim 1, wherein each of the sub-pixels arranged along the first direction emit light of different colors and each of the sub-pixels arranged along the second direction emit the same color each other.

3. The display device of claim 1, wherein the plurality of sub-pixels include the plurality of anode electrodes included in each of the sub-pixels and the repair pattern included in each of the plurality of anode electrode,
wherein the repair pattern extends from the anode electrode along the second direction of the substrate, and disposed in a capacitor area of another sub-pixel, wherein each of the repair pattern arranged on the plurality of sub-pixels are continuously connected to each other along the second direction of the substrate.

4. The display device of claim 1, wherein each of the sub-pixels further includes a sensing transistor,
wherein the sensing transistor includes:
an active layer;
a gate electrode disposed on the active layer; and
source and drain electrodes respectively disposed on both opposing sides of the gate electrode while the gate electrode is interposed therebetween,
wherein one of the source and drain electrodes is electrically connected to the storage capacitor.

5. The display device of claim 4, wherein the storage capacitor connected to the sensing transistor includes:
a first electrode coplanar with the active layer; and
a second electrode coplanar with the gate electrode.

6. The display device of claim 5, wherein one of the source and drain electrodes of the sensing transistor is connected to the second electrode of the storage capacitor.

7. The display device of claim 1, further comprising:
a gate line extending along a first direction of the substrate; and
a data line extending along a second direction intersecting the first direction, wherein the data line distinguishes the sub-pixels disposed adjacent to each other from each other,
wherein the first sub-pixel and the second sub-pixel are arranged along the second direction.

8. The display device of claim 4, further comprising:
a protective layer covering the sensing transistor;
an overcoat film disposed on the protective layer;
a capacitor hole disposed in a capacitor area where the storage capacitor is disposed, wherein the capacitor hole extends through the overcoat film and the protective layer; and
a repair hole disposed in a repair area overlapping with the storage capacitor, wherein the repair hole extends through the overcoat film,
wherein the anode electrode is disposed on an exposed surface of the capacitor hole, and
wherein the repair pattern is disposed in the repair hole so as to contact the protective layer.

9. The display device of claim 8, wherein the repair pattern is disposed in the repair hole and overlapping with the storage capacitor while the protective layer is interposed therebetween.

10. The display device of claim 8, wherein the active layer of the sensing transistor has an area size at least equal to or greater than an area size of the repair hole and contacts the storage capacitor.

11. The display device of claim 1, wherein the repair pattern includes a same material as a material of the second anode electrode and is formed integrally with the second anode electrode.

12. The display device of claim 5, further comprising:
a light-blocking layer disposed under the first electrode of the storage capacitor; and
a buffer layer is interposed between the light-blocking layer and the first electrode of the storage capacitor,
wherein, in a plan view of the device, the light-blocking layer has a recess defined in at least one corner thereof recessed inwardly, wherein the light-blocking layer does not overlap with the second electrode and the repair pattern at the recess.

13. A display device comprising:
a substrate having a sensing area where a sensing transistor is disposed, and a capacitor area including a repair area;
a buffer layer disposed on the substrate and in the sensing area and the repair area;
a light-blocking layer disposed between the substrate and the buffer layer and in a portion of the capacitor area except for the repair area;
a sensing transistor positioned on the buffer layer in the sensing area;
a storage capacitor disposed on the buffer layer and in the capacitor area including the repair area;
a protective layer covering the sensing transistor and the storage capacitor;
an overcoat film disposed on the protective layer;
a repair hole disposed in the repair area and extending through the overcoat film so as to expose a portion of a surface of the protective layer; and
a repair pattern disposed on the repair hole and overlapping with the storage capacitor while the protective layer is interposed between the repair pattern and the storage capacitor.

14. The display device of claim 13, wherein the sensing transistor includes:
an active layer positioned on the buffer layer;
a gate electrode positioned on the active layer; and
source and drain electrodes respectively disposed on both opposing sides of the gate electrode while the gate electrode is interposed between the source and drain electrodes,
wherein one of the source and drain electrodes is electrically connected to the storage capacitor.

15. The display device of claim 13, wherein the storage capacitor connected to the sensing transistor includes:
a first electrode coplanar with the active layer; and
a second electrode coplanar with the gate electrode.

16. The display device of claim 15, wherein the buffer layer further has a buffer hole defined therein exposing a portion of a surface of the substrate in the repair area, and
wherein the second electrode of the storage capacitor fills the buffer hole.

17. The display device of claim 13, further comprising:
a capacitor hole disposed in the capacitor area where the storage capacitor is disposed, wherein the capacitor hole extends through the overcoat film and the protective layer so as to expose a portion of an upper surface of the storage capacitor; and
an anode electrode extending along and on an exposed surface of the capacitor hole and extending on and along an upper surface of the overcoat film.

18. The display device of claim 17, wherein the anode electrode and the repair pattern are made of a same material.

19. A method for repairing a display device, wherein the display device includes:
a substrate including a plurality of sub-pixels;
a first anode electrode and a storage capacitor included in a first sub-pixel in the plurality of sub-pixels; and
a repair pattern extending from a second anode electrode included in a second sub-pixel disposed adjacent to the first sub-pixel, wherein the repair pattern overlap with the storage capacitor of the first sub-pixel,
wherein the method comprises irradiating laser onto the repair pattern extending from the second anode electrode to electrically connect the repair pattern of the second sub-pixel to the storage capacitor of the first sub-pixel.

20. The method of claim 19, wherein the display device further includes:
a protective layer as a single layer disposed between the repair pattern and the storage capacitor; and
a buffer layer disposed between the storage capacitor and the substrate, wherein the buffer layer has a buffer hole defined therein exposing a portion of a surface of the substrate,
wherein the storage capacitor includes a first electrode coplanar with an active layer of a sensing transistor; and a second electrode coplanar with a gate electrode of the sensing transistor,
wherein the second electrode of the storage capacitor fills the buffer hole.

21. The method of claim 19, wherein irradiating the laser includes irradiating the laser to the protective layer as the single layer at an output energy level lower than 500 W.
